(19) United States
(12) Patent Application Publication
(10) Pub. No.: US 2018/0212644 A1
(43) Pub. Date: Jul. 26, 2018

(54) RADIO FREQUENCY FRONT-END CIRCUIT AND IMPEDANCE MATCHING METHOD

(71) Applicant: Murata Manufacturing Co., Ltd., Kyoto (JP)

(72) Inventor: Reiji NAKAJIMA, Kyoto (JP)

(21) Appl. No.: 15/937,047

(22) Filed: Mar. 27, 2018

Related U.S. Application Data
(63) Continuation of application No. PCT/JP2016/074574, filed on Aug. 24, 2016.

(30) Foreign Application Priority Data
Sep. 28, 2015 (JP) 2015-189188

(51) Int. Cl. H04B 1/44; H04L 7/00; H03H 7/38

(52) U.S. Cl. CPC H04B 1/44; H03H 7/38; H04L 7/0016

(57) ABSTRACT

A radio frequency front-end circuit includes an antenna, a circulator, a signal transmission circuit, and first and second variable matching circuits. The first variable matching circuit is connected between the antenna and the signal transmission circuit and variably performs matching of impedance between the antenna and the signal transmission circuit. The second variable matching circuit is connected between the circulator and the signal transmission circuit, variably performs matching of impedance between the signal transmission circuit and the circulator, and further performs, if there is impedance for which matching has not been achieved by the first variable matching circuit, matching of the impedance for which matching has not been achieved.

### BACKGROUND

This is a continuation of International Application No. PCT/JP2016/074574 filed on Aug. 24, 2016 which claims priority from Japanese Patent Application No. JP 2015-189188 filed on Sep. 28, 2015. The contents of these applications are incorporated herein by reference in their entireties.

### TECHNICAL FIELD

The present disclosure relates to a radio frequency front-end circuit that transmits and receives high-frequency radio signals.

A lot of radio communication terminals are currently in practical use. Radio communication terminals include a radio frequency front-end circuit, such as one disclosed in Patent Document 1. The radio frequency front-end circuit disclosed in Patent Document 1 includes a transmission circuit, a reception circuit, a circulator, a branching circuit, and an antenna. The transmission circuit and the reception circuit are connected to the antenna via the circulator and the branching circuit.

A variable matching circuit is connected between the antenna and the branching circuit. Furthermore, a fixed matching circuit is connected between the branching circuit and the circulator. The fixed matching circuit performs impedance matching between a branching circuit side and a circulator side during communication. When the impedance of the antenna departs from a desired value, the variable matching circuit adjusts the impedance by the amount of the departure. When this configuration is provided, the radio frequency front-end circuit disclosed in Patent Document 1 reduces reflection of a transmission signal at the antenna due to departure of impedance, and keeps the transmission signal from leaking to the reception circuit. This provides isolation between the transmission circuit and the reception circuit.

Patent Document 1: International Publication No. 2015/079940

### BRIEF SUMMARY

However, in the case where a fixed matching circuit and a variable matching circuit are used as in the related art, a variable amount is insufficient. For this reason, in the case of a circuit configuration using a circulator, it is difficult to achieve antenna impedance matching on an antenna side of the circulator. Then, in the case where antenna impedance matching has not been achieved on the antenna side of the circulator, because the circulator does not perform separation in accordance with a frequency, a transmission signal reflected by the antenna leaks to a reception side via the circulator, thereby causing deterioration in reception sensitivity.

The present disclosure provides a radio frequency front-end circuit that enables a reduction in the leakage of a transmission signal reflected by an antenna to a reception side via a circulator by causing the impedance of the antenna on an antenna side of the circulator to approach an ideal value closer than that in the existing configuration.

A radio frequency front-end circuit according to the present disclosure includes an antenna, a circulator, a signal transmission circuit, and first and second variable matching circuits. The antenna transmits a transmission signal to the outside and receives a reception signal. The circulator separates the transmission signal and the reception signal. The signal transmission circuit connects the antenna and the circulator. The first variable matching circuit is connected between the antenna and the signal transmission circuit and variably performs matching of impedance between the antenna and the signal transmission circuit. The second variable matching circuit is connected between the circulator and the signal transmission circuit, variably performs matching of impedance between the signal transmission circuit and the circulator, and further performs, if there is impedance for which matching has not been achieved by the first variable matching circuit, matching of the impedance for which matching has not been achieved.

In this configuration, antenna impedance is adjusted by two variable matching circuits, thus increasing an impedance-adjustable range. Furthermore, if there is impedance for which matching has not been achieved by the first variable matching circuit, the second variable matching circuit further performs matching of the impedance for which matching has not been achieved. This provides high isolation between an input terminal for a transmission signal and an output terminal for a reception signal of the circulator and reduces transmission losses for these communication signals.

In the radio frequency front-end circuit according to the present disclosure, in the first variable matching circuit, phases can be adjusted to provide an impedance closest to a theoretical value in an impedance-adjustable range.

In this configuration, in some antenna impedances, impedance matching can be achieved by only the first variable matching circuit. Even if impedance matching performed by the first variable matching circuit is insufficient, impedance matching to the theoretical value performed by the second variable matching circuit is facilitated.

The radio frequency front-end circuit according to the present disclosure can have the following configuration. The radio frequency front-end circuit includes, between the first variable matching circuit and the circulator, a signal detection circuit configured to detect amplitudes and phases of the transmission signal and the reception signal. For the first variable matching circuit and the second variable matching circuit, adjustment amounts of the phases are decided by using the amplitudes and the phases of the transmission signal and the reception signal detected by the signal detection circuit.

In this configuration, adjustment amounts of the phases are decided from the detected amplitudes and phases of the transmission signal and the reception signal, and thus impedance matching is achieved with a higher degree of accuracy.

The radio frequency front-end circuit according to the present disclosure can have the following configuration. The radio frequency front-end circuit further includes an IC circuit. The IC circuit stores an association table in which the amplitudes and the phases of the transmission signal and the reception signal are associated with adjustment amounts of the phases for the first variable matching circuit and the second variable matching circuit. The IC circuit decides on adjustment amounts of the phases for the first variable matching circuit and the second variable matching circuit by using the association table.

In this configuration, adjustment amounts of the phases for the first variable matching circuit and the second variable matching circuit are decided with a reliable and simple process.

In the radio frequency front-end circuit according to the present disclosure, in the first variable matching circuit and the second variable matching circuit, adjustments of the phases can be simultaneously performed.

In this configuration, stable impedance matching is achieved.

The present disclosure makes it possible to more reliably perform impedance matching even if a range of impedance to be matched is wide, provide isolation between transmission and reception in the circulator, and reduce deterioration in reception sensitivity.

### BRIEF DESCRIPTION OF THE SEVERAL VIEWS OF THE DRAWINGS

FIG. 1 is a functional block diagram of a radio frequency front-end circuit according to a first embodiment of the present disclosure.

FIG. 2 is a Smith chart illustrating a concept of antenna impedance adjustment according to the embodiment of the present disclosure.

FIG. 3 illustrates one aspect of an adjustment table for an element value of the radio frequency front-end circuit according to the embodiment of the present disclosure.

FIG. 4 is a circuit diagram of a variable matching circuit according to the embodiment of the present disclosure.

FIGS. 5A-5H include circuit diagrams of components of the variable matching circuit according to the embodiment of the present disclosure.

### DETAILED DESCRIPTION

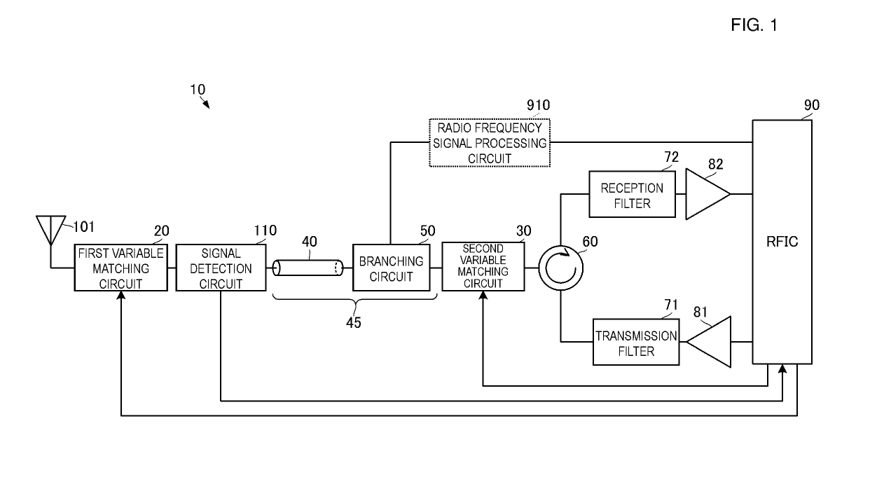

A radio frequency front-end circuit according to an embodiment of the present disclosure will be described with reference to the drawings. FIG. 1 is a functional block diagram of a radio frequency front-end circuit according to a first embodiment of the present disclosure.

A radio frequency front-end circuit 10 includes an antenna 101, a first variable matching circuit 20, a second variable matching circuit 30, a signal cable 40, a branching circuit 50, a circulator 60, a transmission filter 71, a reception filter 72, a PA (power amplifier) 81, an LNA (low-noise amplifier) 82, an RFIC 90, a signal detection circuit 110, and a radio frequency signal processing circuit 910. The signal cable 40 and the branching circuit 50 constitute a signal transmission circuit 45.

The antenna 101 is connected to the first variable matching circuit 20. The first variable matching circuit 20 is connected to the signal detection circuit 110. The signal detection circuit 110 is connected to the signal cable 40 of the signal transmission circuit 45. The signal cable 40 is connected to the branching circuit 50. The branching circuit 50 is connected to the second variable matching circuit 30. The branching circuit 50 is also connected to the radio frequency signal processing circuit 910. The second variable matching circuit 30 is connected to a third terminal of the circulator 60.

The radio frequency signal processing circuit 910 is a circuit that processes a radio frequency signal separated by the branching circuit 50 and includes a circuit that processes a transmission signal and a reception signal.

A first terminal of the circulator 60 is connected to the transmission filter 71, and the transmission filter 71 is connected to the PA 81. A second terminal of the circulator 60 is connected to the reception filter 72, and the reception filter 72 is connected to the LNA 82. The PA 81 and the LNA 82 are connected to the RFIC 90. Also, the radio frequency signal processing circuit 910 is connected to the RFIC 90.

In the radio frequency front-end circuit 10, communication signals in a desired communication band are transmitted and received as described below. A transmission signal and a reception signal in a desired communication band respectively refer to “transmission signal” and “reception signal” of the present disclosure. Transmission and reception may be performed in a time division manner or simultaneously.

### During Transmission

The RFIC 90 generates and outputs a transmission signal to the PA 81. The PA 81 amplifies and outputs the transmission signal to the transmission filter 71. The transmission filter 71 attenuates an unwanted wave, such as a harmonic component, included in the amplified transmission signal and outputs the transmission signal to the circulator 60.

The circulator 60 outputs a radio frequency signal input from the first terminal to the third terminal. A radio frequency signal input from the third terminal is output to the second terminal. Thus, the circulator 60 is a branching device that performs separation in accordance with the directivity of a transmission direction of a radio frequency signal. The circulator 60 transmits the transmission signal input from the first terminal to the third terminal and outputs the transmission signal to the second variable matching circuit 30. The transmission signal input from the first terminal is practically not transmitted to the second terminal.

The second variable matching circuit 30 variably performs matching of the impedance between the signal transmission circuit 45 and the circulator 60 and outputs the transmission signal to the branching circuit 50. The branching circuit 50 is constituted by, for example, any of a diplexer, a duplexer, a switchplexer, and the like. The branching circuit 50 does not cause a communication signal in a communication band different from a communication signal in a communication band separated by the circulator 60 to be transmitted to a circulator 60 side but causes the communication signal to be transmitted to a radio frequency signal processing circuit 910 side. The transmission signal output from the second variable matching circuit 30 is output to the signal detection circuit 110 via the branching circuit 50 and the signal cable 40.

The signal detection circuit 110 outputs the transmission signal to the first variable matching circuit 20. At this time, the signal detection circuit 110 detects an amplitude and a phase of the transmission signal and outputs the amplitude and the phase to the RFIC 90.

The first variable matching circuit 20 variably performs matching of the impedance between the antenna 101 and the signal transmission circuit 45 and outputs the transmission signal to the antenna 101. The antenna 101 transmits (emits) the transmission signal to the outside.

### During Reception

The antenna 101 receives and outputs a reception signal to the first variable matching circuit 20. The first variable matching circuit 20 variably performs matching of the impedance between the antenna 101 and the signal transmission circuit 45 and outputs the reception signal to the signal detection circuit 110.

The signal detection circuit 110 outputs the reception signal to the signal cable 40. The reception signal is output to the branching circuit 50. At this time, the signal detection circuit 110 detects an amplitude and a phase of the reception signal and outputs the amplitude and the phase to the RFIC 90. The reception signal transmitted to the signal cable 40 is input to the branching circuit 50. The branching circuit 50 outputs the reception signal to the second variable matching circuit 30. The second variable matching circuit 30 variably performs matching of the impedance between the signal transmission circuit 45 and the circulator 60 and outputs the reception signal to the third terminal of the circulator 60.

The circulator 60 transmits the reception signal input to the third terminal to the second terminal and outputs the reception signal to the reception filter 72. The reception filter 72 attenuates an unwanted wave component included in the reception signal and outputs the reception signal to the LNA 82. The LNA 82 amplifies and outputs the reception signal to the RFIC 90.

In the radio frequency front-end circuit 10 that has such a configuration and performs such signal processing, the following processing is implemented.

The first variable matching circuit 20 and the second variable matching circuit 30, each includes elements, such as a variable capacitor and a variable inductor, whose element values are adjustable. In an ideal communication condition, that is, in a condition where there is no adverse effect of an external environment, and in a condition where the impedance of the antenna 101 is a theoretical value (for example, an impedance of 50Ω at which communication signals can be transmitted and received with low losses), in the first variable matching circuit 20 and the second variable matching circuit 30, each element value is decided so that impedance matching between the circulator 60 and the antenna 101 is achieved. Here, mainly, the first variable matching circuit 20 is configured so as to achieve impedance matching between the signal transmission circuit 45 and the antenna 101, and the second variable matching circuit 30 is configured so as to achieve impedance matching between the signal transmission circuit 45 and the circulator 60.

Furthermore, in the case where the impedance of the antenna 101 departs from the theoretical value due to, for example, changes in the external environment, the first variable matching circuit 20 and the second variable matching circuit 30 operate in the following manner to adjust the impedance. It is advisable that the first variable matching circuit 20 and the second variable matching circuit 30 simultaneously perform impedance adjustments. This enables achievement of impedance stabilization.

When the impedance when the antenna 101 is viewed from the first variable matching circuit 20 departs from the theoretical value of the antenna impedance, the first variable matching circuit 20 adjusts an element value to variably perform matching of the impedance between the antenna 101 and the signal transmission circuit 45 so that the departure is corrected and removed.

The second variable matching circuit 30 adjusts an element value to adjust phases of a transmission signal and a reception signal so that matching of the impedance between the signal transmission circuit 45 and the circulator 60 is achieved.

Thus, a departure of the antenna impedance is corrected by impedance matching performed by the first variable matching circuit 20 and impedance matching performed by the second variable matching circuit 30.

Because of this, the impedance when an antenna 101 side is viewed from the circulator 60 is equal to or close to the theoretical value, thereby making it possible to keep a transmission signal from being reflected by the antenna 101, returning to the circulator 60, and leaking to a reception filter 72 side. This can provide high isolation between a circuit (transmission circuit) on a transmission filter 71 side and a circuit (reception circuit) on the reception filter 72 side.

As just described above, in the radio frequency front-end circuit 10 according to the embodiment, a plurality of variable matching circuits are used, thereby enables impedance matching in an impedance range wider than a range of impedance adjustable by one variable matching circuit. Thus, even a departure of the antenna impedance over a wider impedance range can be adjusted.

Furthermore, the second variable matching circuit 30 not only performs an antenna impedance adjustment, but also performs impedance matching between the signal transmission circuit 45 and the circulator 60, thereby enabling a reduction in circuit size in comparison with the case where the antenna impedance adjustment and the impedance matching are performed by respective different variable matching circuits. Thus, in the radio frequency front-end circuit 10 according to the embodiment, a departure of the antenna impedance can be corrected in a wide range while keeping the circuit size from increasing.

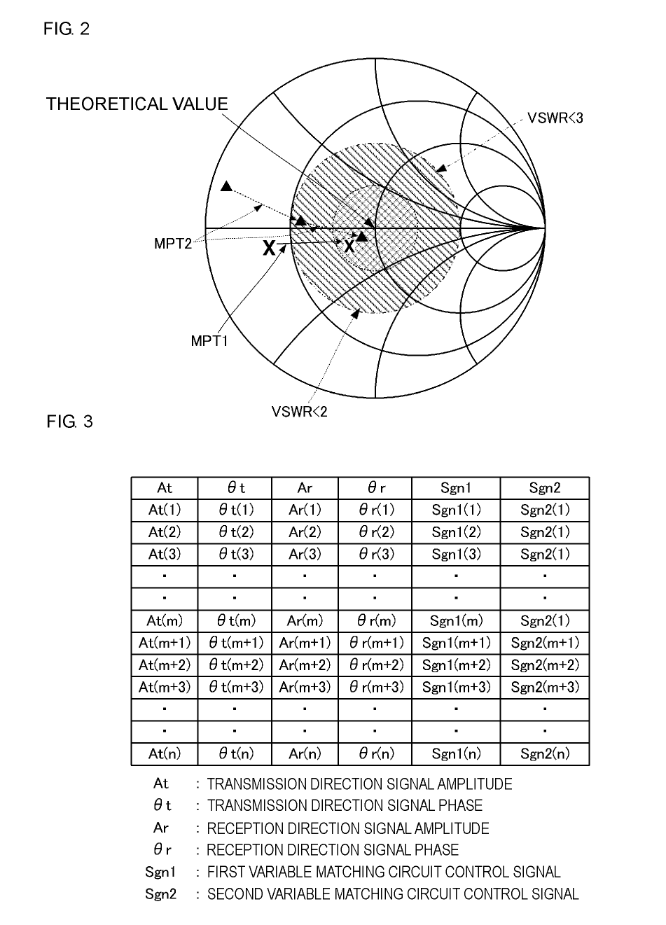

To achieve the above-described correction in the radio frequency front-end circuit 10, element values of the first variable matching circuit 20 and the second variable matching circuit 30 are adjusted so that an impedance shift indicated on a Smith chart to be described is achieved. FIG. 2 is a Smith chart illustrating a concept of antenna impedance adjustment according to the embodiment of the present disclosure. As illustrated in FIG. 2, a region around an impedance of 50Ω enclosed by a dash-dot-dot line is a region in which a VSWR is less than three. Furthermore, as illustrated in FIG. 2, a region around the impedance of 50Ω enclosed by a dotted line is a region in which a VSWR is less than two. In most cases, even in the case of VSWR<3, transmission and reception by the antenna 101 are possible. However, in the radio frequency front-end circuit 10 according to the embodiment, transmission and reception by the antenna 101 are desirably performed in a VSWR<2 state. That is, in the radio frequency front-end circuit 10 according to the embodiment, VSWR=2 is a threshold for determining whether impedance matching has been achieved. The threshold can be appropriately set in accordance with, for example, specifications of a communication device including the radio frequency front-end circuit 10.

### First Aspect

As indicated by x-marks representing impedances before and after correction and by an arrow MPT1 representing an impedance shift, in the Smith chart, although an impedance before correction is outside a VSWR=3 circle, an impedance corrected by the first variable matching circuit 20 is inside a VSWR=2 circle (the region of VSWR<2). This makes it possible to achieve antenna impedance matching.

In this case, although the impedance can be caused to approach the theoretical value closer by the second variable matching circuit 30, this approach does not necessarily have to be made. The use of such processing can reduce the consumption of electric power for adjusting an element value of the second variable matching circuit 30 and can reduce the power consumption of the radio frequency front-end circuit 10.

### Second Aspect

As indicated by x-marks representing impedances before and after correction and by arrows MPT2 representing impedance shifts, in the Smith chart, although an impedance before correction is outside the VSWR=3 circle, an impedance corrected by the first variable matching circuit 20 is inside the VSWR=3 circle (the region of VSWR<3) and outside the VSWR=2 circle (a region of VSWR>2). When additional correction is performed by the second variable matching circuit 30, a corrected impedance is inside the VSWR=2 circle (the region of VSWR<2). This makes it possible to achieve antenna impedance matching. Thus, the use of the radio frequency front-end circuit 10 according to the embodiment enables antenna impedance matching for a wider impedance range.

In adjusting element values, it is advisable to satisfy the following conditions. An element value is adjusted so as to achieve the closest approach to the theoretical value in a range of impedance variable by each variable matching circuit. This can provide higher isolation between the transmission circuit and the reception circuit.

Furthermore, in the second aspect in which both the first variable matching circuit 20 and the second variable matching circuit 30 are used, element values are adjusted so that the length of the locus of impedances obtained by performing element value adjustments becomes shortest. Such adjustments are performed, thereby making it possible to keep a variable range of each element value of each variable matching circuit from unnecessarily increasing, and form the element as small as possible, for example.

Next, a specific method of adjusting and controlling element values of the first variable matching circuit 20 and the second variable matching circuit 30 will be described. FIG. 3 illustrates one aspect of an adjustment table for an element value of the radio frequency front-end circuit according to the embodiment of the present disclosure.

The RFIC 90 stores an adjustment table illustrated in FIG. 3. As illustrated in FIG. 3, in the adjustment table, a transmission direction signal amplitude At, a transmission direction signal phase θt, a reception direction signal amplitude Ar, a reception direction signal phase θr, a first variable matching circuit control signal Sgn1, and a second variable matching circuit control signal Sgn2 are associated with one another. The first variable matching circuit control signal Sgn1 and the second variable matching circuit control signal Sgn2 are set so that element values that achieve optimal antenna impedance matching are provided by the first variable matching circuit 20 and the second variable matching circuit 30 in a combination of the transmission direction signal amplitude At, the transmission direction signal phase θt, the reception direction signal amplitude Ar, and the reception direction signal phase θr that are associated in the adjustment table.

The RFIC 90 acquires an amplitude of a transmission signal detected by the signal detection circuit 110 as a transmission direction signal amplitude At, and acquires a phase of the transmission signal as a transmission direction signal phase θt. The RFIC 90 acquires an amplitude of a reception signal detected by the signal detection circuit 110 as a reception direction signal amplitude Ar, and acquires a phase of the reception signal as a reception direction signal phase θr.

The RFIC 90 compares a combination of the transmission direction signal amplitude At, the transmission direction signal phase θt, the reception direction signal amplitude Ar, and the reception direction signal phase θr that have been acquired with the adjustment table and decides on a first variable matching circuit control signal Sgn1 and a second variable matching circuit control signal Sgn2. The RFIC 90 outputs the first variable matching circuit control signal Sgn1 decided in accordance with the adjustment table to the first variable matching circuit 20, and outputs the second variable matching circuit control signal Sgn2 decided in accordance with the adjustment table to the second variable matching circuit 30. The first variable matching circuit 20 adjusts an element value based on the first variable matching circuit control signal Sgn1. The second variable matching circuit 30 adjusts an element value based on the second variable matching circuit control signal Sgn2.

When such processing is performed, element values of the first variable matching circuit 20 and the second variable matching circuit 30 are decided based on a transmission signal and a reception signal that are actually being transmitted. Thus, antenna impedance can be optimally set. At this time, with the addition of a concept of a locus or the like on the above-described Smith chart, more efficient and optimal impedance matching can be achieved.

Furthermore, FIG. 3 illustrates the case where, in a transmission direction signal amplitude At(1)'s combination to a transmission direction signal amplitude At(m)'s combination, their respective second variable matching circuit control signals Sgn2 are a Sgn2(1), that is, they are constant. This refers to the case where impedance matching can be achieved by only the above-described first variable matching circuit 20. In this case, as long as impedance matching is performed within this range, a new second variable matching circuit control signal Sgn2 does not have to be output to the second variable matching circuit 30, thereby enabling still lower power consumption.

Furthermore, although the aspect in which the adjustment table is used has been given in the above description, in the case where a first variable matching circuit control signal Sgn1 and a second variable matching circuit control signal Sgn2 can be decided by a mathematical operation using a transmission direction signal amplitude At, a transmission direction signal phase θt, a reception direction signal amplitude Ar, and a reception direction signal phase θr, an arithmetic expression may be stored, and a first variable matching circuit control signal Sgn1 and a second variable matching circuit control signal Sgn2 may be calculated by using the arithmetic expression.

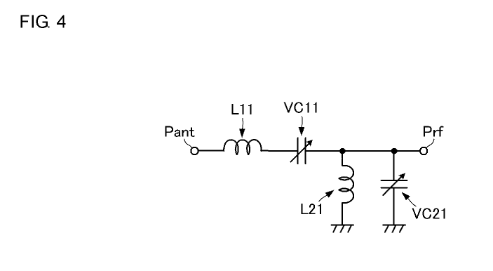

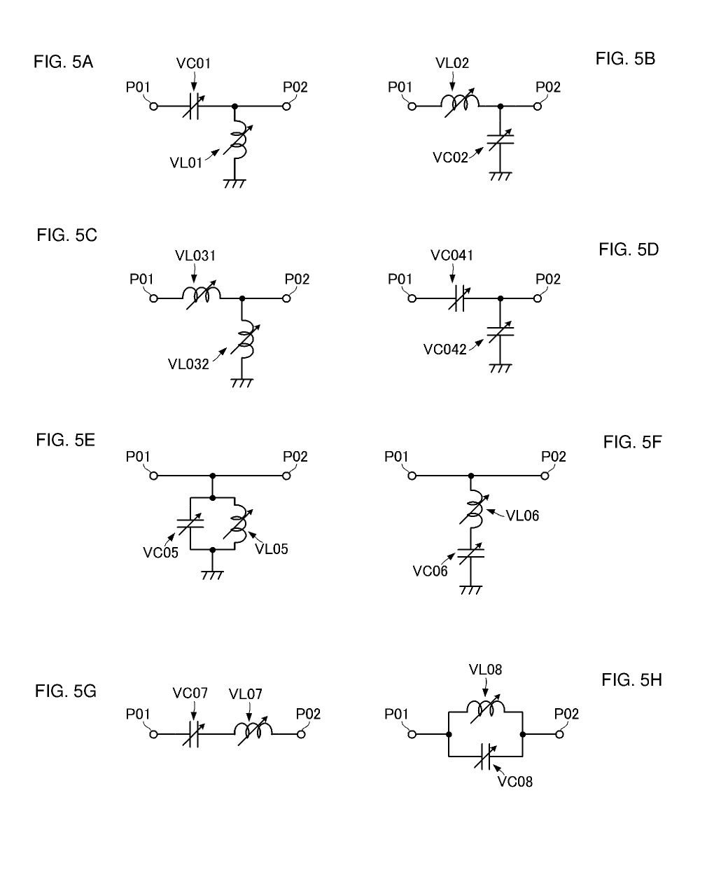

Next, an example of a specific circuit configuration of the first variable matching circuit 20 and the second variable matching circuit 30 will be described with reference to FIGS. 4 and 5. FIG. 4 is a circuit diagram of a variable matching circuit according to the embodiment of the present disclosure.

As illustrated in FIG. 4, a variable matching circuit includes an antenna-side terminal Pant and an RF-side terminal Prf. For example, in the first variable matching circuit 20, the antenna-side terminal Pant is connected to the antenna 101, and the RF-side terminal Prf is connected to the signal cable 40. In the second variable matching circuit 30, the antenna-side terminal Pant is connected to the branching circuit 50, and the RF-side terminal Prf is connected to the circulator 60.

The variable matching circuit includes inductors L11 and L21, and variable capacitors VC11 and VC21. The inductor L11 and the variable capacitor VC11 are connected in series. An end portion on an inductor L11 side of this series circuit is connected to the antenna-side terminal Pant. An end portion on a variable capacitor VC11 side of this series circuit is connected to the RF-side terminal Prf.

An RF-side terminal Prf side of the variable capacitor VC11 is connected to a ground potential via the inductor L21 and the variable capacitor VC21.

When such a configuration is provided, a variable capacitor is connected in series with and a variable capacitor is connected in parallel with a transmission line connecting the antenna-side terminal Pant and the RF-side terminal Prf, thereby enabling an increase in an impedance-adjustable range.

Furthermore, it is more advisable that the variable matching circuit includes at least one of components illustrated in FIGS. 5A-5H. FIGS. 5A-5H include circuit diagrams of components of the variable matching circuit according to the embodiment of the present disclosure.

Components illustrated in FIGS. 5A-5H, each includes a first terminal P01 and a second terminal P02. A component of FIG. 5A includes a variable capacitor VC01 and a variable inductor VL01. The variable capacitor VC01 is connected between the first terminal P01 and the second terminal P02. The variable inductor VL01 is connected between a second terminal P02 side of the variable capacitor VC01 and a ground potential. A component of FIG. 5B includes a variable capacitor VC02 and a variable inductor VL02. The variable inductor VL02 is connected between the first terminal P01 and the second terminal P02. The variable capacitor VC02 is connected between a second terminal P02 side of the variable inductor VL02 and the ground potential. A component of FIG. 5C includes variable inductors VL031 and VL032. The variable inductor VL031 is connected between the first terminal P01 and the second terminal P02. The variable inductor VL032 is connected between a second terminal P02 side of the variable inductor VL031 and the ground potential. A component of FIG. 5D includes variable capacitors VC041 and VC042. The variable capacitor VC041 is connected between the first terminal P01 and the second terminal P02. The variable capacitor VC042 is connected between a second terminal P02 side of the variable capacitor VC041 and the ground potential. A component of FIG. 5E includes a variable capacitor VC05 and a variable inductor VL05. The variable capacitor VC05 and the variable inductor VL05 are connected in parallel. This parallel circuit is connected between a transmission line connecting the first terminal P01 and the second terminal P02 and the ground potential. A component of FIG. 5F includes a variable capacitor VC06 and a variable inductor VL06. The variable capacitor VC06 and the variable inductor VL06 are connected in series. This series circuit is connected between the transmission line connecting the first terminal P01 and the second terminal P02 and the ground potential. A component of FIG. 5G includes a variable capacitor VC07 and a variable inductor VL07. The variable capacitor VC07 and the variable inductor VL07 are connected in series. This series circuit is connected between the first terminal P01 and the second terminal P02. A component of FIG. 5H includes a variable capacitor VC08 and a variable inductor VL08. The variable capacitor VC08 and the variable inductor VL08 are connected in parallel. This parallel circuit is connected between the first terminal P01 and the second terminal P02.

The components illustrated in FIGS. 5(A) to 5(H), each includes a plurality of variable elements whose element values are variable. Such a configuration in which a plurality of variable elements are provided enables an increase in an impedance-adjustable range. The number of variable elements may be three or more and may be appropriately set in accordance with a relationship between a circuit size limit and an impedance-adjustable range.

Although a variable capacitor or a variable inductor may be a variable capacitor or a variable inductor whose element value is continuously variable or discretely variable, the variable capacitor or the variable inductor whose element value is continuously variable is effective at increasing the number of impedances that can be provided.

Furthermore, although an increase in an impedance-adjustable range has been given as a feature in the above description, the use of this principle can cause the antenna impedance to approach the theoretical value closer to provide higher isolation even in a narrow impedance-adjustable range.

### REFERENCE SIGNS LIST

10 radio frequency front-end circuit

20 first variable matching circuit

30 second variable matching circuit

40 signal cable

45 signal transmission circuit

50 branching circuit

60 circulator

71 transmission filter

72 reception filter

81 PA

82 LNA

90 RFIC

101 antenna

110 signal detection circuit

910 radio frequency signal processing circuit

1. A radio frequency front-end circuit comprising:
an antenna configured to transmit a transmission signal and receive a reception signal;
a circulator configured to separate the transmission signal and the reception signal;
a signal transmission circuit connecting the antenna and the circulator;
a first variable matching circuit connected between the antenna and the signal transmission circuit, and configured to variably match an impedance between the antenna and the signal transmission circuit; and
a second variable matching circuit connected between the circulator and the signal transmission circuit, and configured to variably match an impedance between the signal transmission circuit and the circulator,
wherein, if the first variable matching circuit does not match the impedance between the antenna and the signal transmission circuit, the second variable matching circuit is further configured to match an impedance between the circulator and the antenna.

2. The radio frequency front-end circuit according to claim 1,
wherein the first variable matching circuit is configured to adjust a phase of the transmission signal or the reception signal to approach an impedance closest to a theoretical value in an impedance-adjustable range.

3. The radio frequency front-end circuit according to claim 1, further comprising:
a signal detection circuit connected between the first variable matching circuit and the circulator, and configured to detect an amplitude and a phase of the transmission signal or of the reception signal,
wherein the first variable matching circuit and the second variable matching circuit are configured to adjust the phase of the transmission signal or of the reception signal by an amount determined based on the detected amplitude and the detected phase of the transmission signal or of the reception signal.

4. The radio frequency front-end circuit according to claim 2, further comprising:
a signal detection circuit connected between the first variable matching circuit and the circulator, and configured to detect an amplitude and a phase of the transmission signal or of the reception signal,
wherein the first variable matching circuit and the second variable matching circuit are configured to adjust the phase of the transmission signal or of the reception signal based on the detected amplitude and the detected phase of the transmission signal or of the reception signal.

5. The radio frequency front-end circuit according to claim 3, further comprising a radio frequency integrated circuit (RFIC) configured to:
store an association table in which amplitudes and phases of the transmission signal and of the reception signal are associated with phase adjustment amounts for the transmission signal and the reception signal, for each of the first variable matching circuit and the second variable matching circuit, and
decide a phase adjustment amount to be used by the first variable matching circuit and the second variable matching circuit based on the association table.

6. The radio frequency front-end circuit according to claim 2,
wherein the first variable matching circuit and the second variable matching circuit are configured to simultaneously adjust the phase of the transmission signal or of the reception signal.

7. The radio frequency front-end circuit according to claim 3,
wherein the first variable matching circuit and the second variable matching circuit are configured to simultaneously adjust the phase of the transmission signal or of the reception signal.

8. The radio frequency front-end circuit according to claim 4,
wherein the first variable matching circuit and the second variable matching circuit are configured to simultaneously adjust the phase of the transmission signal or of the reception signal.

9. The radio frequency front-end circuit according to claim 5,
wherein the first variable matching circuit and the second variable matching circuit are configured to simultaneously adjust the phase of the transmission signal or of the reception signal.

10. An impedance matching method comprising:
transmitting a transmission signal from an antenna via a circulator and a signal transmission circuit;
receiving a reception signal with the antenna and outputting the reception signal to the circulator via the signal transmission circuit;
separating the transmission signal and the reception signal with the circulator;
variably matching an impedance between the antenna and the signal transmission circuit;
variably matching an impedance between the signal transmission circuit and the circulator; and
if the impedance between the antenna and the signal transmission circuit is not matched, matching an impedance between the circulator and the antenna.

11. The radio frequency front-end circuit according to claim 10,
wherein the impedance between the antenna and the signal transmission circuit is matched by adjusting a phase of the transmission signal or the reception signal to approach an impedance closest to a theoretical value in an impedance-adjustable range.

12. The radio frequency front-end circuit according to claim 10, further comprising:
detecting an amplitude and a phase of the transmission signal or of the reception signal via a signal detection circuit connected between the antenna and the circulator,
wherein the impedance between the antenna and the signal transmission circuit and the impedance between the signal transmission circuit and the circulator are matched by adjusting the phase of the transmission signal or of the reception signal by an amount determined based on the detected amplitude and the detected phase of the transmission signal or of the reception signal.

13. The radio frequency front-end circuit according to claim 12,
wherein the impedance between the antenna and the signal transmission circuit and the impedance between the signal transmission circuit and the circulator are matched simultaneously.
